(19) United States
(12) Patent Application Publication
(10) Pub. No.: US 2009/0191680 A1
(43) Pub. Date: Jul. 30, 2009

(54) DUAL-GATE MEMORY DEVICE WITH CHANNEL CRYSTALLIZATION FOR MULTIPLE LEVELS PER CELL (MLC)

(76) Inventor: Andrew J. Walker, Mountain View, CA (US)

Correspondence Address: Haynes and Boone, LLP;IP Section, 2323 Victory Avenue, SUITE 700, Dallas, TX, 75219, US

(21) Appl. No.: 12/419,994

(22) Filed: Apr. 7, 2009

Related U.S. Application Data
(62) Division of application No. 11/866,899, filed on Oct. 3, 2007.

(51) Int. Cl. H01L 21/336; H01L 21/20

(52) U.S. Cl. 438/283; 438/486; 257/E21.409; 257/E21.09

(57) ABSTRACT

A method and a dual-gate memory device having a memory transistor and an access transistor are provided to allow multiple bits to be stored in the dual-gate memory device. The memory transistor and the access transistor each have a channel region formed in a mobility enhanced material crystallized from an amorphous semiconductor material. The amorphous semiconductor material may include, for example, silicon. Mobility enhancement may be achieved by: (a) Excimer laser annealing; (b) lateral crystallization; (c) metal-induced lateral crystallization; (d) a combination of laser annealing and metal-induced laterally crystallization steps; or (e) solid-phase, epitaxially growth.

### CROSS-REFERENCE TO RELATED APPLICATION

This application is a divisional of U.S. patent application Ser. No. 11/866,899 filed Oct. 3, 2007 entitled “DUAL-GATE MEMORY DEVICE WITH CHANNEL CRYSTALLIZATION FOR MULTIPLE LEVELS PER CELL (MLC),” the disclosure of which is incorporated by reference herein in its entirety.

### BACKGROUND OF THE INVENTION

1. Field of the Invention

The present invention relates to semiconductor memory devices. In particular, the present invention relates to dual-gate memory devices providing multiple-bit storage per memory cell.

2. Discussion of the Related Art

Discrete-trap NAND flash memory devices provide the advantage of scalability, which is much desired in floating gate memory devices. Discrete traps may be formed in silicon nitride, silicon oxynitride, or nanocrystals, replacing the conventional floating gate conductor. The discrete-trap approach using silicon nitride was described in the article, “A Novel SONOS Structure of SiO₂/SiN/Al₂O₃n with TaN Metal Gate for Multi-giga bit Flash Memories” (the “Lee 2003 article”), by C. H. Lee et al, published in the International Electronic Device Meeting (IEDM) 2003, Technical Digest, pp. 613-616. The Lee 2003 article describes a classic NAND string that includes memory transistors connected in series, with each memory transistor having an aluminum oxide gate dielectric provided adjacent a gate electrode, a silicon nitride trapping layer and a tunnel oxide layer adjacent a channel region. The approach discussed in the Lee 2003 article suffers from severe “read pass” and “program pass” disturbs, which affect the unselected cells in a selected NAND string. To avoid these disturbs, a gate voltage is applied that is larger than the worst-case programmed threshold voltage (plus a design margin). This applied gate voltage disturbs the charge contents in an unselected memory cell, especially when the memory cell is in an erased (i.e., low threshold voltage) state. FIG. 1, which is FIG. 5 of the article “Charge Trapping Memory Cell of TANOS (Si-Oxide-SiN—Al₂O₃—TaN) Structure Compatible to Conventional NAND Flash Memory” (the “Lee 2006 article”), by C. H. Lee et al., published at the VLSI Symposium, 2006, plots the lifetimes of a TANOS memory cell, defined as the time required to shift the threshold voltage of an erased cell by 2 volts, as a function of the read pass voltage V_{read}. As seen from FIG. 1, the lifetimes fall below 100 seconds when V_{read} exceeds 6.5 volts, for a 63 nm TANOS memory device, as reported in the Lee 2006 article. The vulnerability to disturb by such memory cells makes unlikely such memory cells to be used as multi-level cells (MLCs), since the voltage margins between levels is inadequate to reliably avoid misreading of the levels.

### SUMMARY OF THE INVENTION

According to one embodiment of the present invention, a method and a dual-gate memory device—a memory device having a memory transistor and an access transistor—are provided to allow multiple bits to be stored in the dual-gate memory device. In that embodiment, the memory transistor and the access transistor each have a channel region formed in a mobility enhanced material crystallized from an amorphous semiconductor layer. The amorphous semiconductor may include, for example, silicon.

According to one embodiment of the present invention, mobility enhancement may be achieved by: (a) Excimer laser annealing; (b) lateral crystallization; (c) metal-induced lateral crystallization; (d) a combination of laser annealing and metal-induced lateral crystallization steps; or (e) solid-phase epitaxial growth.

Because the dual-gate memory device has high immunity to disturbs, the dual-gate memory device is suitable for storing multiple bits of information in each memory cell in the dual-gate memory device. Crystallization of channel silicon increases the current range within which different current levels, corresponding to the multiple levels, may be provided.

Sequential lateral solidification is one crystallization technique well-suited to dual-gate string structure, since the channels may be aligned to a pre-determined direction for enhanced carrier mobility in the channels.

The present invention is better understood upon consideration of the detailed description below in conjunction with the accompanying drawings.

### BRIEF DESCRIPTION OF THE DRAWINGS

FIG. 1 is a plot showing the lifetimes of a non-volatile memory cell, as defined by the time required to shift the threshold voltage of an erased cell by 2 volts, as a function of the read pass voltage V_{read}.

FIG. 2 shows, in a memory cell in a dual-gate memory device, immunity of a programmed high threshold voltage to the read pass voltage.

FIG. 3 shows the string currents in a 64-bit dual-gate string for various read pass voltages, and as a function of the selected memory device's gate voltage.

FIGS. 4A-4M illustrate a method suitable for forming a dual-gate string non-volatile semiconductor memory device, according to one embodiment of the present invention.

FIG. 5 shows room-temperature mobility of the laterally crystallized polysilicon thin-film transistors, as a function of film thickness and channel orientation.

FIG. 6 is a graph showing the distribution of currents for a 2-bit memory cell, in accordance with one embodiment of the present invention.

### DETAILED DESCRIPTION OF THE PREFERRED EMBODIMENTS

U.S. patent application “Dual-Gate Memory Device and Optimization of Electrical Interaction Between Front And Back Gates To Enable Scaling” (“Copending application”) by Andrew Walker, Ser. No. 11/749,094, filed on May 15, 2007, discloses a dual-gate approach to a high density flash memory structure which prevents such disturbs. The disclosure of the Copending application is hereby incorporated by reference in its entirety to provide technological background for the present invention.

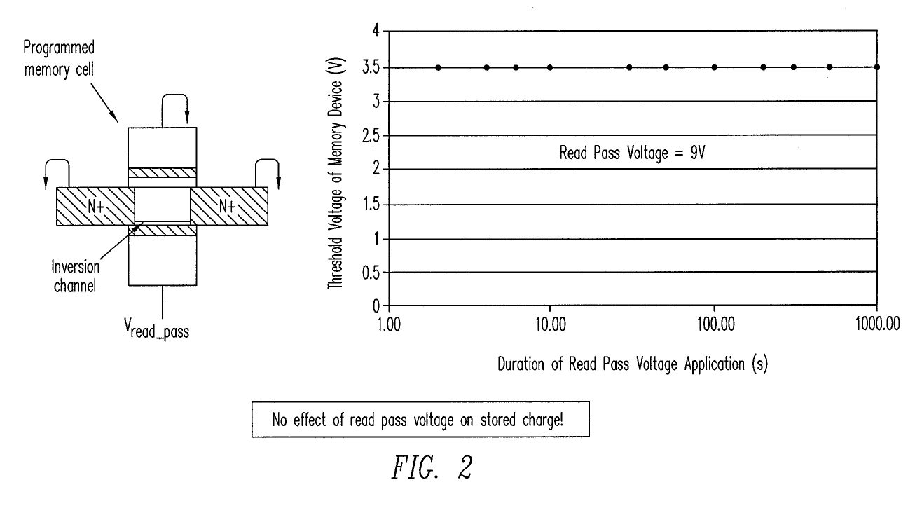

FIG. 2 shows, in a memory cell in a dual-gate memory device, long-term immunity of a programmed high threshold voltage to the read pass voltage. The programmed state (high threshold voltage state) is the more sensitive one to shifts in the dual-gate case since the access device's gate voltage would tend to erase the state by attracting stored electrons through the tunnel oxide. As shown in FIG. 2, even after applying 9 volts on a gate electrode of the access device for 1000 seconds, no shift in the threshold voltage of the memory device is measured. In a dual-gate memory cell, the electrical interaction between the access device and the memory device, when one is inverted, provides electrical shielding. As disclosed in the Copending application, without inversion, the electrical interaction is present to allow enhanced scaling.

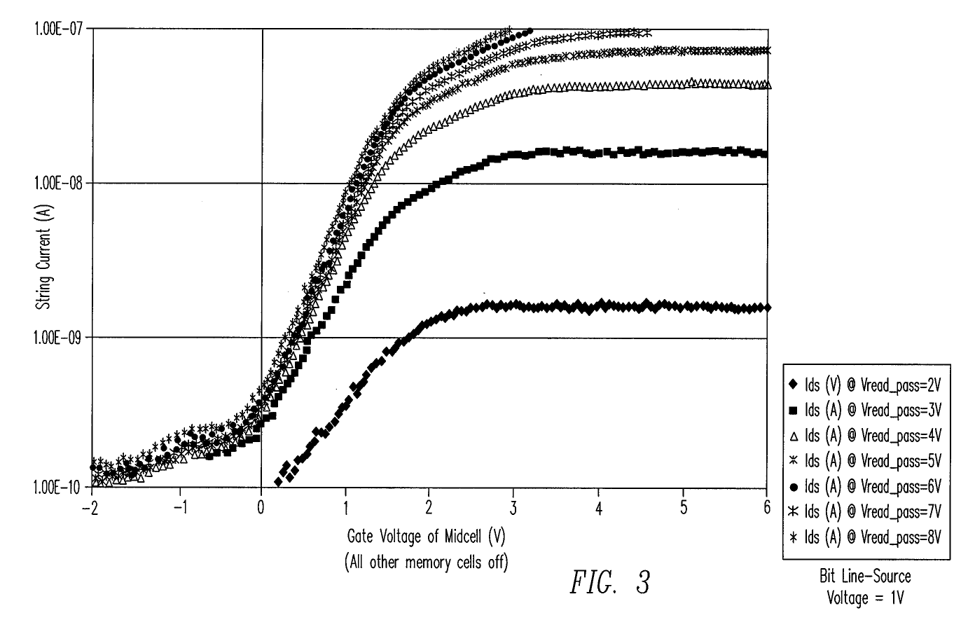

Since the dual-gate approach to a high density Flash structure reduces disturb, such a structure is particularly desirable for implementing MLCs. However, for a dual-gate device with a polysilicon channel, the total string current is typically between 10's of nano-amps to 100's of nano-amps, which is challenging for an MLC approach. For example, FIG. 3 shows the string currents in a 64-bit dual-gate string for various read pass voltages, and as a function of the selected memory device's gate voltage. In FIG. 3, the maximum current is shown to be just over 100 nA. To provide several threshold voltage levels (e.g., 2^{N} levels, if storing N bits in each memory cell is desired), the channel current levels preferable span between about 100 nano-amps to several micro-amps. One technique to increase the range of available channel currents uses a crystallization technique, which improves both the mobility of the channel charge carriers and the current handling capability of the dual-gate string.

Suitable crystallization techniques include:
(a) Excimer laser annealing (ELA)—in ELA, one or more shots of laser energy are applied to the channel silicon, normally deposited in the amorphous phase¹ and left unpatterned or patterned prior to laser irradiation; ¹ See, e.g., the article “A High-Performance Polysilicon Thin-Film Transistor using XeCl Eximer Laser Crystallization of Pre-Patterned Amorphous Si Films,” by M. Cao et al., published in IEEE Trans. Elect. Dev., vol. 43, pp. 561-567, April 1996.
(b) Lateral crystallization—in lateral crystallization (e.g., sequential lateral solidification (SLS)), a shaped laser beam is moved across the channel silicon to crystallize the channel silicon²; ² See, e.g., the article “Assessment of the Performance of Laser-Based Lateral-Crystallization Technology via Analysis and Modeling of Polysilicon Thin-Film-Transistor Mobility,” by A. T. Voutsas, published in IEEE Trans. Elect. Dev., vol. 50, pp. 1494-1500, June 2003; see, also, the article “Sequential Lateral Solidification Processing for Polycrystalline Si TFTs,” by M. A. Crowder et al., published in the IEEE Trans. Elect. Dev., vol. 51, pp. 560-568, April 2004; see, also, the article “MONOS Memory in Sequential Laterally Solidified Low-Temperature Polysilicon TFTs,” by S. I. Hsieh et al., published in the IEEE Elect. Dev. Lett., vol. 27, pp. 272-274, April 2006.
(c) Metal-Induced Lateral Crystallization (MILC)—in MILC, a metal such as nickel is deposited in a window of silicon dioxide to contact deposited channel amorphous silicon, followed by heat treatment to crystallize³ the channel silicon; ³ See, e.g., the article “Reduction of Leakage Current in Metal-Induced Lateral Crystallization Polysilicon TFTs with Dual-Gate and Multiple Nanowire Channels,” by Y. C. Wu et al., published in the IEEE Elect. Dev. Lett., vol. 26, pp. 646-648, September 2005.
(d) a combination of MILC and laser treatment⁴; and ⁴ See, e.g., the article “An Investigation of Laser Annealed and Metal-Induced Crystallized Polycrystalline Silicon Thin Film Transistors,” by D. Murley et al., published in the IEEE Trans. Elect. Dev., vol. 48, pp. 1145-1151, June 2001.
(e) solid-phase epitaxial (SPE) growth—in SPE growth, amorphous channel silicon grows as single crystal using a single crystal “seed” in, for example, the wafer substrate.

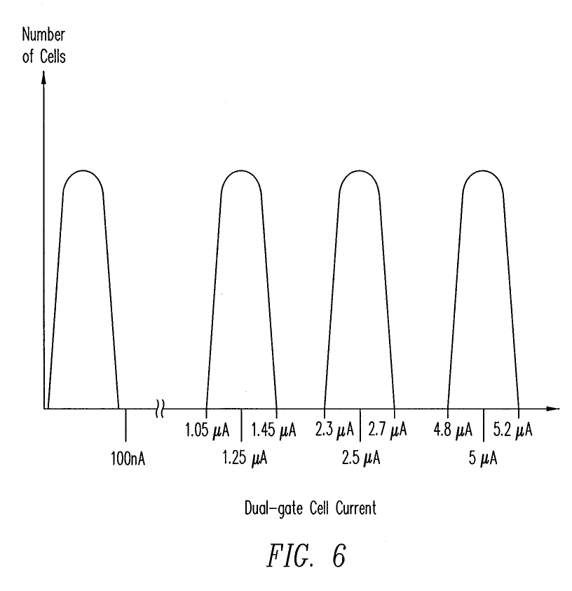

With an enhanced mobility channel, a source of programming voltages may be used to generate a number of discrete programming voltages to program the memory device to various programmed states corresponding to various discrete conduction currents in the channel. FIG. 6 is a graph showing the distribution of currents for a 2-bit memory cell, in accordance with one embodiment of the present invention. As shown in FIG. 6, the memory cell may be programmed to have four programmed states, providing channel conduction currents at <100 nA, 1.25±0.2 μA, 2.5±0.2 μA, and 5.0±0.2 μA, respectively. The erased state is the one associated with the maximum current distribution (centered in this case around 5.0 μA). The most highly programmed state in this case is the one where the current distribution is all less than 100 nA.

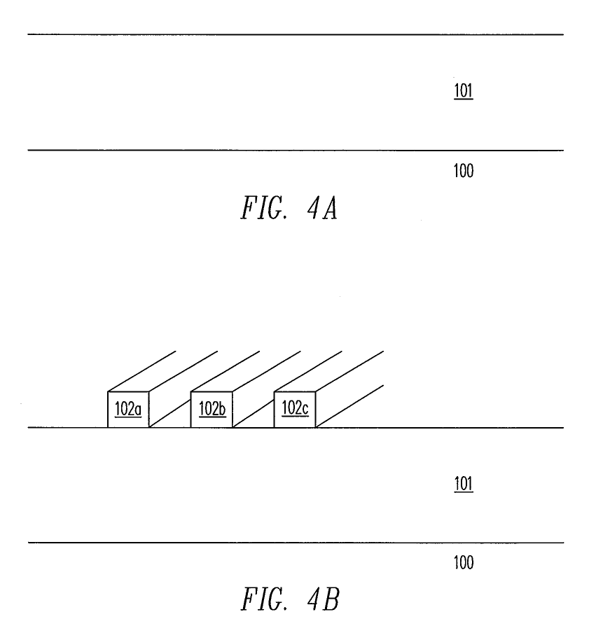

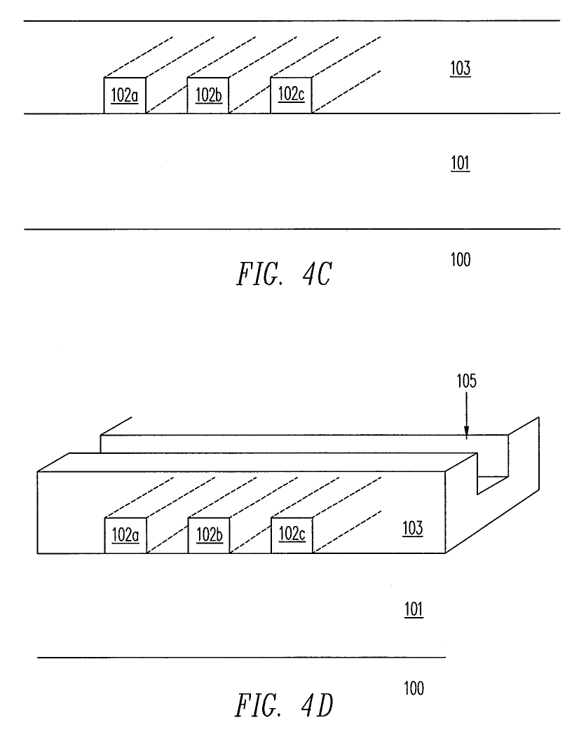

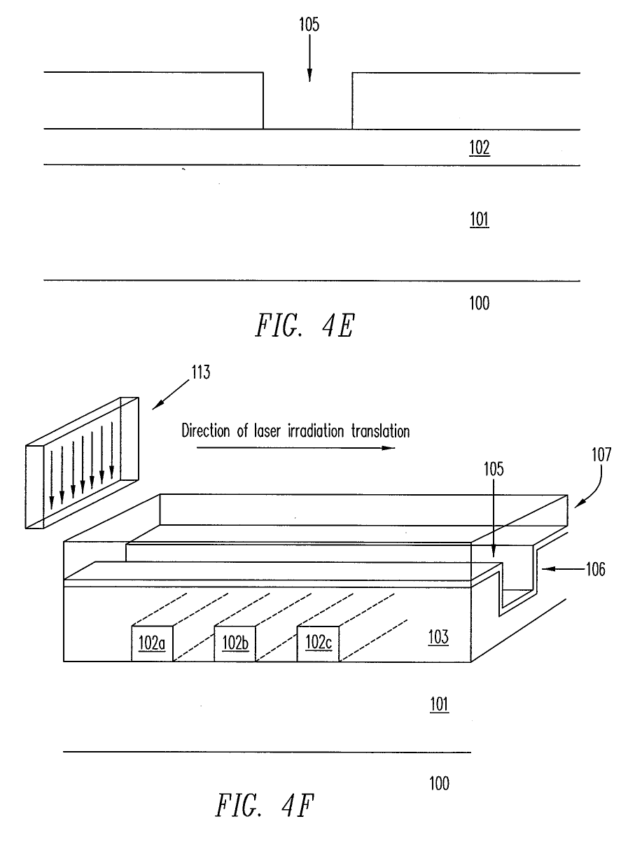

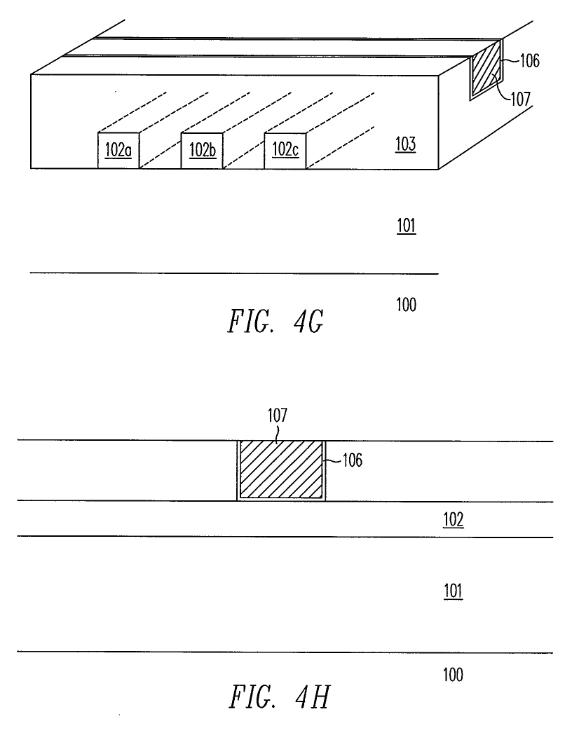

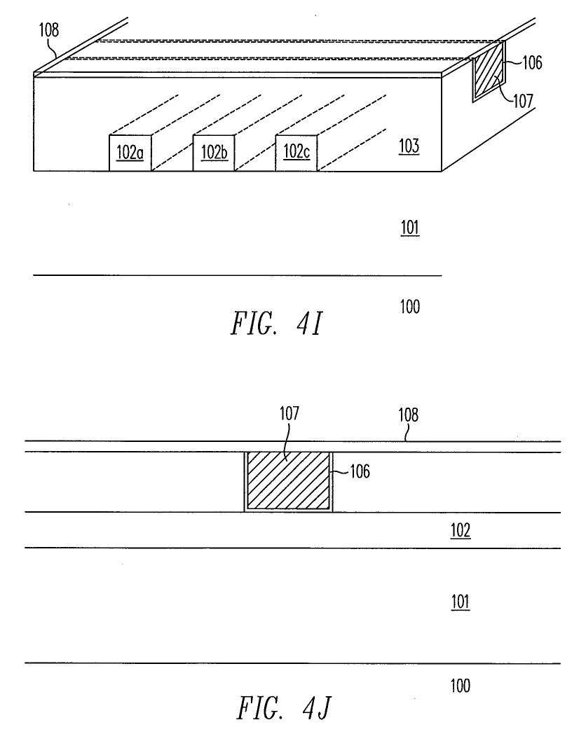

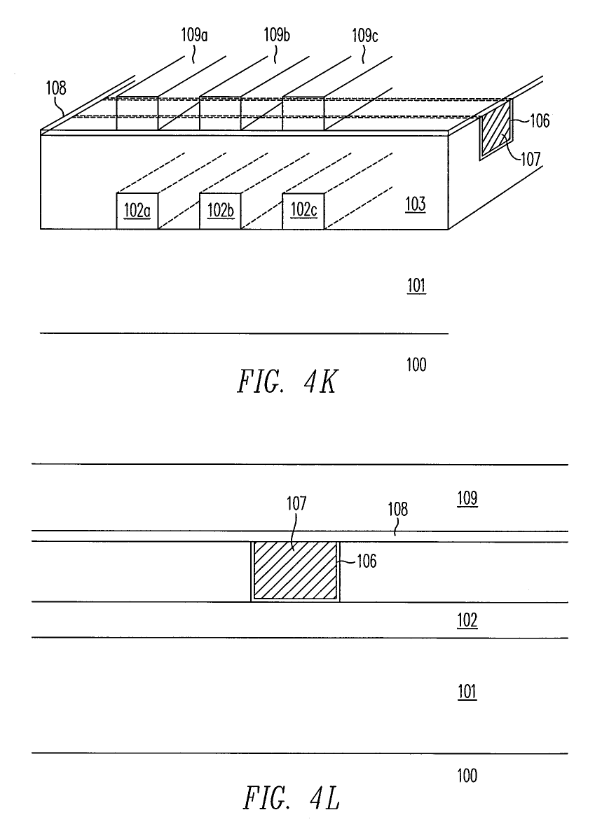

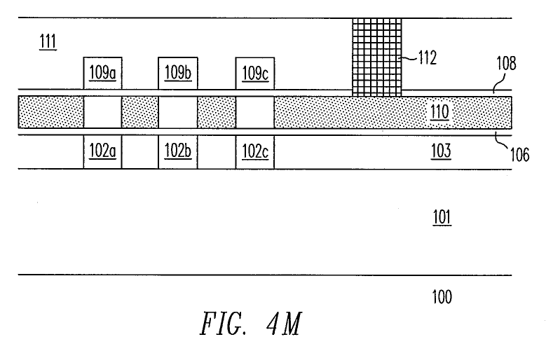

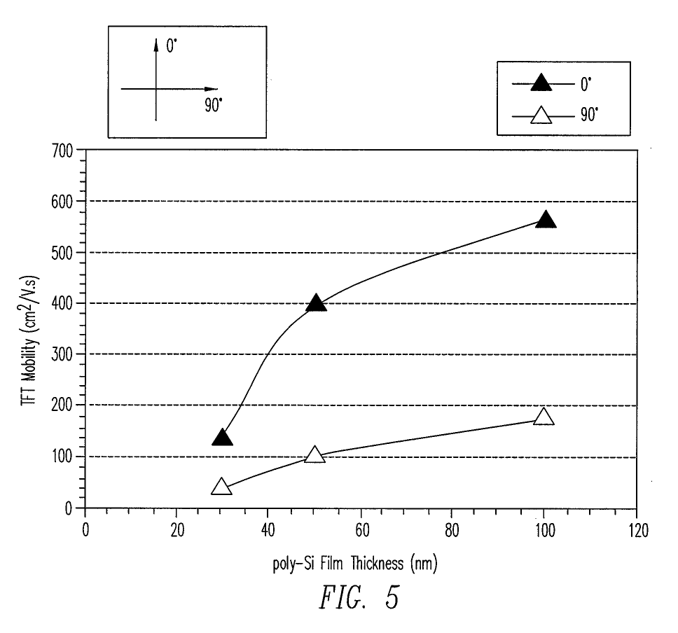

FIGS. 4A-4M illustrate a method suitable for forming a dual-gate string non-volatile semiconductor memory device, according to one embodiment of the present invention.

FIG. 4A shows insulating layer 101 provided on substrate 100. Substrate 100 may be a semiconductor wafer containing integrated circuitry for controlling a non-volatile memory. The semiconductor wafer may be either of a bulk type, where the substrate is made of a single crystal of semiconductor, such as silicon, or of a semiconductor-on-insulator type, such as silicon on insulator (SOI), where the integrated circuitry is made in the thin top silicon layer. Insulating layer may be planarized using conventional chemical mechanical polishing (CMP). Within insulating layer 101 may be embedded vertical interconnections (not shown in FIG. 4) for connecting the integrated circuitry with the non-volatile memory device. Such interconnections may be made using conventional photolithographic and etch techniques to create contact holes, followed by filling the contact holes with a suitable type of conductor, such as a combination of titanium nitride (TiN) and tungsten (W), or a heavily doped polysilicon.

Next, a conducting material 102 is provided on top of insulating layer 101 using conventional deposition techniques. Material 102 may also include a stack of two or more conducting materials formed in succession. Suitable materials for material 102 include heavily doped polysilicon, titanium disilicide (TiSi₂), tungsten (W), tungsten nitride (WN), cobalt silicide (CoSi₂), nickel silicide (NiSi) or combinations of these materials. Conventional photolithographic and etch techniques are used to pattern gate electrode word lines 102a, 102b and 102c, as shown in FIG. 4B. These word lines form the gate electrode word lines for the access devices to be formed, according to one embodiment of the present invention.

Next, an insulating layer 103 is provided over word lines 102a, 102b and 102c. Insulating layer 103 may be provided using high density plasma (HDP), chemical vapor deposition (CVD), plasma enhanced CVD (PECVD), physical vapor deposition (PVD) or may be a spin on glass (SOG). The surface is then planarized using a conventional CMP step, which either may polish insulating layer 103 down to the surface of the word lines 102a, 102b and 102c, or timed such that a controlled thickness remains of insulating layer 103 between the surface of the word lines 102a, 102b and 102c and the top polished surface of insulating layer 103. In the former case, after CMP, a controlled thickness of an insulating material is deposited using one of the techniques discussed above. Under either approach, the result is shown in FIG. 4C.

Next, trenches 105 are etched into insulating layer 103 using conventional photolithographic and etch techniques. The etching exposes at least the surface of the word lines 102a, 102b and 102c and removes a portion of insulating layer 103. Over-etching may also take place, so long as no detriment is made to the electrical working of the eventual completed structure. FIG. 4D shows trench 105 after formation. The trenches are formed in a direction perpendicular to word lines 102a, 102b and 102c. FIG. 4E shows a cross section through both trench 105 and word line 102, which runs along the plane of FIG. 3E. Trench 105 may be 50 Å to 3000 Å thick, preferably about 500 Å. Trenches 105 may be formed in a trench etch which also removes a portion of each word line 102. Such an etch may be achieved by over-etching (using plasma etching, for example) of insulating material 105 into a portion of word lines 102. Thus, the bottom of trench 105 may be situated below the top surface of each word line 102.

Next, thin dielectric layer 106 is formed on top of the structure shown in FIG. 4E. Thin dielectric layer 106 forms the gate dielectric of the access device and may be formed using a conventional method, such as thermal oxidation in an oxidizing ambient, low pressure CVD (LPCVD) deposition of a dielectric material, such as silicon dioxide, silicon nitride, silicon oxynitride, high temperature oxide (HTO), PECVD dielectric (e.g., silicon oxide or silicon nitride), atomic layer deposition (ALD) of silicon oxide, or some high-k dielectric material. The effective oxide thickness may be in the range of 10 Å and 400 Å.

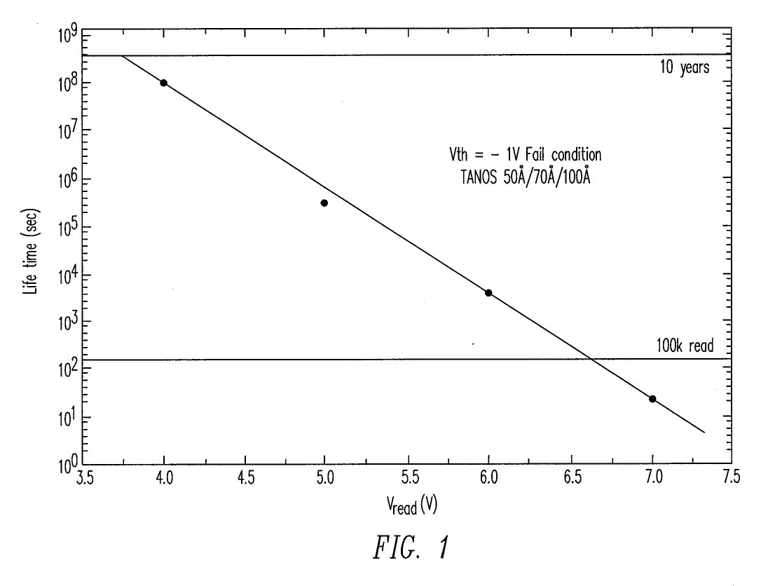

Next, active semiconductor layer 107 is formed by depositing a semiconductor material, such as polycrystalline silicon (polysilicon), polycrystalline germanium, amorphous silicon, amorphous germanium or a combination of silicon and germanium, using conventional techniques such as LPCVD or PECVD. Polycrystalline material may be deposited as a first step as an amorphous material. The amorphous material may then be crystallized using heat treatment or laser irradiation. In one embodiment, sequential lateral solidification (SLS), such as shown in FIG. 4F, is carried out after the channel silicon has been deposited in an amorphous state. The direction of translation of the shaped laser beam 113 is parallel to the direction of the eventual channels, so as to obtain high carrier mobility. This effect is shown in FIG. 5. FIG. 5 shows room-temperature mobility of the laterally crystallized polysilicon thin-film transistors, as a function of film thickness and channel orientation. FIG. 5, which is FIG. 1 in the article “Assessment of the Performance of Laser-Based Lateral-Crystallization Technology via Analysis and Modeling of Polysilicon Thin-Film-Transistor Mobility,” by A. T. Voutsas, published in IEEE Trans. Elect. Dev., vol. 50, pp. 1494-1500, June 2003, shows significantly higher channel mobility when the lateral growth direction is parallel to the channel.

Crystallized semiconductor layer 107 is formed sufficiently thick, so as to completely fill trench 105 (e.g., at least half the width of trench 105). After deposition, the part of the semiconductor material above trench 105 is removed using, for example, either CMP, or plasma etching. Using either technique, the semiconductor material can be removed with very high selectivity relative to insulating layer 103. For example, CMP of polysilicon can be achieved with selectivity with respect to silicon oxide of several hundred to one. The representative result using either technique is shown in FIG. 4G.

FIG. 4H shows a cross section made through trench 105 and word line 102. Word line 102 runs in a direction parallel to the cross section plane of FIG. 4H. Thin dielectric layer 106 forms the gate dielectric layer of the access device and material 107 is the semiconductor material remaining in trench 105 after the material is substantially removed from the surface of insulating layer 103. Material 107 forms the active semiconductor layer for both the memory device and the access device of the dual-gate device. Material 107 may be undoped or may be doped using conventional methods, such as ion implantation, or in-situ doping carried out in conjunction with material deposition. A suitable doping concentration is between zero (i.e., undoped) and 5×10¹⁸/cm³, and may be p-type for an NMOS implementation or n-type for a PMOS implementation. The thickness of material 107 is selected such that the sensitivity parameter is less than a predetermined value (e.g., 0.8).

Next, dielectric layer 108 is provided, as shown in FIG. 4I. Dielectric layer 108, which is the dielectric layer for the memory device in the dual-gate device, may be a composite ONO layer consisting of a bottom 10 Å to 80 Å thick thin silicon oxide, an intermediate 20 Å to 200 Å silicon nitride layer, and a top 20 Å to 100 Å silicon oxide layer. (Other materials may take the place of the silicon nitride layer, such as silicon oxynitride, silicon-rich silicon nitride, or a silicon nitride layer that has spatial variations in silicon and oxygen content.) Conventional techniques may be used to form these layers. The bottom thin silicon oxide layer may be formed using thermal oxidation in an oxidizing ambient, low pressure oxidation in a steam ambient, or LPCVD techniques that deposits a thin layer of silicon oxide, such as high temperature oxide (HTO). Atomic layer deposition (ALD) may also be used to form the bottom thin silicon oxide layer. The intermediate layer may be formed using LPCVD techniques or PECVD techniques. The top silicon oxide layer may be formed using, for example, LPCVD techniques, such as HTO, or by depositing a thin amorphous silicon layer, followed by a silicon oxidation in an oxidizing ambient.

Alternatively, dielectric layer 108 may be a composite layer consisting of silicon oxide, silicon nitride, silicon oxide, silicon nitride and silicon oxide (ONONO), using the techniques discussed above. As discussed above, the silicon nitride may be replaced by silicon oxynitride, silicon-rich silicon nitride, or a silicon nitride layer that has spatial variations in silicon and oxygen content. Alternatively, an ONONONO layer may be used. Such multiplayer composites may be tailored such that the electric charge stored within dielectric layer 108 persists for longer periods.

Alternatively, dielectric layer 108 may contain a floating gate conductor for charge storage that is electrically isolated from both the gate electrode of the memory device to be formed and the active semiconductor layer. The floating gate conductor may comprise nano-crystals that are placed between the gate electrode and the active semiconductor layer 107. Suitable conductors may be silicon, germanium, tungsten, or tungsten nitride.

Alternatively to charge storage in dielectric layer 108, the threshold voltage shifts may also be achieved by embedding a ferroelectric material whose electric polarization vector can be aligned to a predetermined direction by applying a suitable electric field.

Alternatively, dielectric layer 108 may be a composite layer of silicon oxide, silicon nitride or oxynitride and a high-k (high dielectric constant) dielectric such as aluminum oxide.

FIG. 4J shows a cross section of the forming dual-gate structure through word line 102, after the step forming dielectric layer 108.

Next, conducting material 109 is provided over dielectric layer 108 using conventional deposition techniques. Conducting material 109 may comprise a stack of two or more conducting materials. Suitable materials for conducting material 109 include heavily doped polysilicon, titanium disilicide (TiSi₂), tungsten (W), tungsten nitride (WN), cobalt silicide (CoSi₂), nickel silicide (NiSi), titanium nitride (TiN), tantalum nitride (TaN) or combinations of these materials. Conventional photolithographic and etch techniques are used to form gate electrode word lines 109a, 109b and 109c, as is shown in FIG. 4K. These word lines form the gate electrode word lines of the forming memory devices, and run substantially parallel to the underlying access gate electrode word lines 102a, 102b and 102c. FIG. 4L shows a cross section through word lines 102 and 109, after the step forming word lines 109a, 109b and 109c.

Next, source and drain regions are formed within active semiconductor layer 107 using conventional methods such as ion implantation. For an NMOS implementation, n-type ions may be implanted with a dose between 1×10¹²/cm² and 1×10¹⁶/cm², using ionic species such as arsenic, phosphorus or antimony. For a PMOS implementation, p-type ions may be implanted at substantially the same dose range. P-type ionic species may include boron, boron difluoride, gallium or indium. The ion implantation provides source and drain regions that are self-aligned to the gate electrode word lines 109a, 109b and 109c. The result is illustrated in FIG. 3L in which regions 110 represent the heavily doped source and drain regions. In one embodiment, these source and drain regions extend from the top surface of active semiconductor layer 107 to its bottom surface. The source and drain regions may be formed using a combination of ion implantation and subsequent thermal steps to diffuse the dopant atoms introduced.

Next, insulating layer 111 may be provided using high density plasma (HDP), CVD, PECVD, PVD or a spin on glass (SOG). The surface may then be planarized using a conventional CMP step. The result is shown in FIG. 4M.

Vertical interconnections 112 may then be formed using conventional photolithographic and plasma etching techniques to form small holes down to gate electrodes 109a, 109b 109c, heavily doped semiconductor active regions 110 and gate electrodes 102a, 102b and 102c. The resulting holes are filled with a conductor using conventional methods, such as tungsten deposition (after an adhesion layer of titanium nitride has been formed) and CMP, or heavily doped polysilicon, followed by plasma etch back or CMP. The result is shown in FIG. 3M.

Subsequent methods may be carried out to further interconnect the dual-gate devices with other dual-gate devices in the same layer or in different layers and with the circuitry formed in the substrate 100.

Although FIG. 4 (i.e., FIGS. 4A-4M) illustrates a method which forms the access device (i.e., the non-memory device) before forming the memory device, by making dielectric layer 108 charge-storing and dielectric layer 106 non-charge storing, the memory device may be formed before the non-memory device. Irrespective of which order is chosen, the operations of the memory device and non-memory device are substantially the same. FIG. 4 therefore illustrates forming a dual-gate memory device with access gate 102, access gate dielectric 106, semiconductor active region 107, memory dielectric 108, memory gate electrode 109 and source and drain regions 110.

Therefore, as the dual-gate high density flash memory has high immunity to disturbs, such a structure is ideal for providing multiple levels per memory cell. Crystallization of channel silicon increases the current range within which different current levels, corresponding to the multiple levels, may be provided. As demonstrated above, sequential lateral solidification is one crystallization technique well-suited to the dual-gate string structure, since the channels may be aligned to a pre-determined direction for enhanced carrier mobility in the channels. Other examples of suitable crystallization techniques include (a) single or multiple shot excimer laser annealing; (b) MILC; (c) MILC plus laser annealing; and (e) Solid phase epitaxial (SPE) growth.

The above detailed description is provided to illustrate specific embodiments of the present invention. Numerous variations and modifications within the scope of the present invention are possible. The present invention is set forth in the following claims.

I claim:

1. A method for providing a dual-gate memory device, comprising:
forming a layer of amorphous semiconductor material;
crystallizing the amorphous semiconductor material to form a crystallized semiconductor layer using a mobility enhancement technique; and
forming in the crystallized semiconductor layer a channel region for a memory transistor of the dual-gate memory device, a channel region for an access transistor of the dual-gate memory device and common source-drain regions for the memory transistor and the access transistor of the dual gate device.

2. A method claim 1, wherein the amorphous semiconductor material comprises silicon.

3. A method in claim 1, wherein the mobility enhancement technique comprises annealing the crystallized semiconductor using Excimer lasers.

4. A method as in claim 1, wherein the mobility enhancement technique comprises a lateral crystallization step.

5. A method as in claim 1, wherein the mobility enhancement technique comprises a metal-induced lateral crystallization step.

6. A method as in claim 1, wherein the mobility enhancement technique comprises a combination of laser annealing and metal-induced laterally crystallization steps.

7. A method as in claim 1, wherein the mobility enhancement technique comprises carrying out a solid-phase, epitaxial growth step.

8. A method as in claim 1, further comprising forming a nano-crystal material layer as a charge storage layer for the memory transistor, the nano-crystal material being selected from the group consisting of silicon, germanium, tungsten, or tungsten nitride.

9. A method as in claim 1, further comprising forming a charge storage layer that comprises a composite material consisting of one or more of silicon oxide, silicon nitride or oxynitride and a high dielectric constant dielectric.

10. A method in claim 1, further comprising programming the memory device to any one of a plurality of predetermined programmed states.

11. A method as in claim 10, wherein each programmed state corresponds to a predetermined conductivity in the channel region of the memory transistor.
